(19) United States
(12) Patent Application Publication
(10) Pub. No.: US 2026/0031827 A1
(43) Pub. Date: Jan. 29, 2026

(54) SYSTEMS AND METHODS FOR ADAPTIVE FILTERING OF SPURIOUS SIGNALS IN AN ANALOG-TO-DIGITAL CONVERTER (ADC)

(71) Applicant: NXP USA, Inc., Austin, TX (US)

(72) Inventor: Frederic Georges-Ferdinand Barghi, Le Rouret (FR)

(21) Appl. No.: 19/272,122

(22) Filed: Jul. 17, 2025

(30) Foreign Application Priority Data
Jul. 24, 2024 (EP) 24306248.6

(51) Int. Cl. H03M 1/06

(52) U.S. Cl. CPC H03M 1/0626

(57) ABSTRACT

Systems and methods for adaptive filtering in an Analog-to-Digital Converter (ADC) address the issue of spurious tones affecting the Signal-to-Noise Ratio (SNR). In an illustrative, non-limiting embodiment, a system may include a processor configured to execute program instructions for estimating and compensating spurious signals in the ADC output. The system may identify the frequency, phase, and amplitude of spurious signals using Gi-Gq computation. In some cases, the ADC output path and spurious estimation processing may be oversampled to compensate for high-frequency spurs (e.g., closely below the ADC's Nyquist frequency). Also, such a system may operate before or during the reception of the signal, ensuring no impact on the useful signal reception and reducing power consumption. In another illustrative, non-limiting embodiment, a method may include adaptive filtering or cancellation of unwanted tones by learning and applying coefficients to the in-phase (I) and quadrature (Q) components of a digital signal.

### FIELD

This disclosure relates generally to electronic circuits, and more specifically, to systems and methods for adaptive filtering of spurious signals in an Analog-to-Digital Converter (ADC).

### BACKGROUND

Analog-to-Digital Converters (ADCs) often produce or capture multi-tone spurious signals from various sources, including frequency generation subsystems, power management subsystems, connectivity subsystems, and RF subsystems. These spurious signals can significantly impact the Signal-to-Noise Ratio (SNR) of the ADC, thereby limiting the performance of subsystems. Applications using such subsystems may be impacted in multiple ways from quality to functional safety.

### BRIEF DESCRIPTION OF THE DRAWINGS

The present disclosure is illustrated by way of example and are not limited by the accompanying figures, in which like references indicate similar elements. Elements in the figures are illustrated for simplicity and clarity and have not necessarily been drawn to scale.

FIG. 1 is a block diagram of an example of an electronic device, according to some embodiments.

FIG. 2 is a flowchart of an example of a method for adaptive filtering in an Analog-to-Digital Converter (ADC), according to some embodiments.

FIG. 3 is a diagram of an example of a spurious signal cancellation circuit, according to some embodiments.

FIG. 4 is a diagram of an example of a quadrature wave generation circuit with frequency error compensation within a control unit of the spurious signal cancellation circuit, according to some embodiments.

FIG. 5 is a diagram of an example of a processing circuit within a processing unit of the spurious signal cancellation circuit, according to some embodiments.

FIG. 6 is a diagram of an example of Received Signal Strength Indicator (RSSI) and frequency error estimation circuit within the processing circuit, according to some embodiments.

FIG. 7 is a graph illustrating examples of adaptive filtering operations, according to some embodiments.

### DETAILED DESCRIPTION

Analog-to-Digital Converters (ADCs) are components in a wide range of electronic devices, including consumer electronics, communication systems, medical equipment, industrial automation systems, automotive electronics, and scientific instrumentation. These converters are responsible for transforming analog signals into digital data, enabling the processing and analysis of various types of information.

ADCs often produce or capture unwanted tones or signals from various sources, such as frequency generation subsystems, power management subsystems, and connectivity and RF subsystems. These “spurious signals” are typically not part of the desired signal and can interfere with it, significantly impacting the Signal-to-Noise Ratio (SNR) of the ADC and thereby limiting the performance of applications such as RF receivers and sensors.

Existing solutions to mitigate the impact of these multi-tone spurious signals on ADCs include the use of low-pass filters and other filtering techniques. However, these methods are often inadequate, especially when unwanted signals occur within the signal bandwidth. Low-pass filters are unsuitable for this purpose as they cannot effectively distinguish between the desired signal and the spurious signals.

Additionally, conventional adaptive filtering techniques that rely on learning rate coefficients can be slow and computationally intensive, leading to suboptimal performance in real-time applications.

To address these, and other concerns, systems and methods described herein may generate digital signals, controlled in frequency, phase, and amplitude, to track and cancel unwanted multi-tones reported at the ADC output. These systems and methods may learn the coefficients applied to the in-phase (I) and quadrature (Q) components of a digital sinewave signal operating at the unwanted frequency to cancel the unwanted signal in the time domain.

Systems and methods described herein may concurrently or simultaneously cancel multiple signals and can operate either before or during the reception of the useful signal. Additionally, these systems and methods may derive a Received Signal Strength Indicator (RSSI) of the unwanted signal to decide if cancellation activation is required and analyze the standard deviation phase of the unwanted signal to validate the assumption of a narrowband interference.

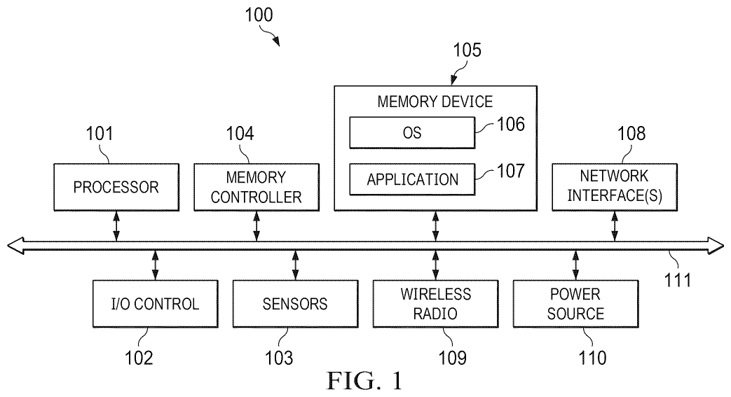

FIG. 1 shows an example of electronic device 100 where systems and methods for adaptive filtering in an ADC may be implemented. In various embodiments, device 100 may be integrated with electronic circuitry, microprocessors, microcontrollers, memory, input output (I/O) logic control, communication interfaces and components, as well as other hardware, firmware, or software. Moreover, one or more components of device 100 may be part of a Systems-on-Chip (SoC) or heterogenous computing platform.

Device 100 includes processor 101 (e.g., a controller, a microcontroller, a digital signal processor, etc.) configured to execute program instructions stored in memory device 105 for implementing various systems and methods described herein. Processor 101 may include components of an integrated circuit, programmable logic device, a logic device formed using one or more semiconductors, and other implementations in silicon or hardware.

In some cases, processor 101 may include two domains: (i) a low-power microprocessor, core, or domain, and (ii) a high-power microprocessor, core, or domain. The high-power microprocessor may execute computationally intensive operations, whereas the low-power microprocessor may manage simpler processes, such as detecting inputs from one or more sensors. The low-power processor may also wake or initialize the high-power processor for computationally intensive processes. More generally, processor 101 may include any number of such domains.

In device 100, data bus 111 couples its various components and enables data communication between those components. Data bus 111 may be implemented as any suitable combination of one or more bus structures or bus architectures. Device 100 also includes power source 110, such as a battery or an AC-DC power supply.

Sensors 103 may be implemented to detect various properties such as acceleration, temperature, humidity, water, supplied power, proximity, external motion, device motion, sound signals, ultrasound signals, light signals, fire, smoke, carbon monoxide, Global-Positioning-Satellite (GPS) signals, radio frequency (RF), other electromagnetic signals or fields, or the like. As such, sensors 103 may include any one or a combination of temperature sensors, humidity sensors, hazard-related sensors, other environmental sensors, accelerometers, microphones, optical sensors up to and including cameras (e.g., charged coupled-device or video cameras, active or passive radiation sensors, GPS receivers, and RF identification (ID) detectors).

Memory controller 104 and memory device 105 may implement any type of nonvolatile memory or other suitable electronic storage device. Device 100 may include various firmware or software, such as Operating System (OS) 106 maintained as computer executable instructions in memory 105 and executed by processor 101.

Moreover, application 107 may include a distance estimation application that implements various aspects of the systems and methods described herein.

Input-output (I/O) control 102 may be configured to receive input from a user or provide information to the user. For example, I/O control 102 may also include mechanical or virtual components that respond to a user input. For example, the user can mechanically move a sliding or rotatable component, or the motion along a touchpad may be detected, and may correspond to a setting of device 100.

Device 100 includes network interfaces 108, such as a mesh network interface for communication with other devices in a wireless mesh network, and an external network interface for network communication, such as via the Internet. Wireless radio system 109 may be used for wireless communication with other devices via network interface 108 and for multiple, different wireless communications systems. For instance, radio system 109 may include a radio device, antenna, and chipset implemented for any given wireless communications technology, such as, for example, Wi-Fi, BLUETOOTH (BT), BT Low-Energy (BLE), Mobile Broadband, point-to-point IEEE 802.15.4, etc.

Among the various components of device 100, ADCs are typically found in several key areas. For example, processor 101, which may include digital signal processors (DSPs) and microcontrollers, often handles analog inputs that require conversion to digital data. Sensors 103, such as microphones, accelerometers, and optical sensors, also rely on ADCs to convert analog signals into digital form. Additionally, wireless radio system 109 uses ADCs to convert received Radio Frequency (RF) signals into digital data for subsequent processing.

The output of an ADC may be modeled by considering the amplitude (A) and phase (φ) of the spurious signals, along with the intrinsic noise (N) of the ADC. The spurious signal at the ADC output may be represented as:

$$A D {C}_{out} ( n {T}_{s} ) = A \times cos ( ω \times n {T}_{s} + φ ) + N ( n {T}_{s} ) .$$

This equation can be further expanded using trigonometric identities:

$$A D {C}_{out} ( n {T}_{s} ) = A \times cos ( φ ) \times cos ( ω \times n {T}_{s} ) - A \times sin ( φ ) \times sin ( ω \times n {T}_{s} ) + N ( n {T}_{s} ) .$$

We can define the in-phase (I) and quadrature (Q) components as:

$$\begin{matrix}Gi ( A , φ ) = A \times cos ( φ ) ; and \\ Gq ( A , φ ) = - A \times sin ( φ ) .\end{matrix}$$

Thus, the ADC output may be restated as:

$${ADC}_{out} ( {nT}_{s} ) = Gi ( A , φ ) \times cos ( ω \times {nT}_{s} ) + Gq ( A , φ ) \times sin ( ω \times {nT}_{s} ) + N ( {nT}_{s} ) .$$

Here, N (nTₛ) represents the additional noise resulting from the ADC's intrinsic noise and the analog thermal noise at the ADC input. As described in more detail below, systems and methods described herein may generate digital reference signals:

$$\begin{matrix}{I}_{ref \_ dig} = cos ( ω \times {nT}_{s} ) ; and \\ {Q}_{ref \_ dig} = sin ( ω \times {nT}_{s} )\end{matrix}$$

These systems and methods may implement an algorithmic loop to find estimated values of coefficients Gi and Gq referred as [symbol] (A, φ) and [symbol] (A, φ) respectively, that minimize the metric std (Errₒᵤₜ), where Errₒᵤₜ may be defined as:

$${Err}_{out} ( {nT}_{s} ) = {ADC}_{out} ( {nT}_{s} ) - ( ( A , φ ) \times {I}_{ref} + ( A , φ ) \times {Q}_{red} ) .$$

Moreover, these systems and methods may assess A and @ based on [symbol] (A, φ) and [symbol] (A, φ) using the following equations:

$$\begin{matrix}A \hat{}= √ ( ( A , φ ) 2 + ( A , φ ) 2 ) ; and \\ φ \hat{}= - atan ( ( A , φ ) / ( A , φ ) ) .\end{matrix}$$

Sometimes the tones are produced by devices sharing the reference clock of ADC itself. In those cases, the frequency of the tones is often known and the systems and methods described herein provide a mechanism for assessing (Gi,Gq) to cancel each tone. In other cases, particularly when the spurious signals are introduced by a device other than the receiver using ADCs (e.g., a transmitter), systems and methods described herein may, in addition, estimate a frequency error first before compensation. In yet other cases, this frequency error may be derived from the application itself (such as carrier frequency offset assessment in RF communication systems) and the systems and methods described herein may only compensate the frequency error and assess (Gi,Gq) to cancel the unwanted tone.

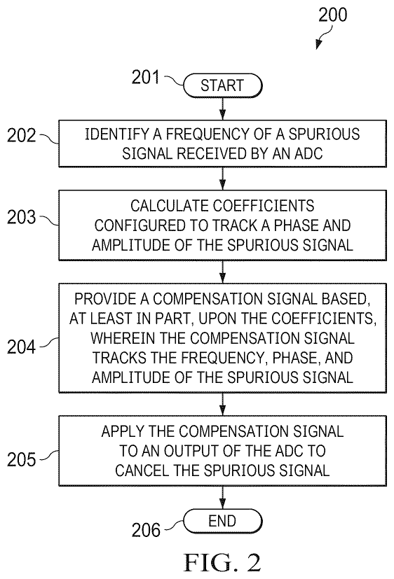

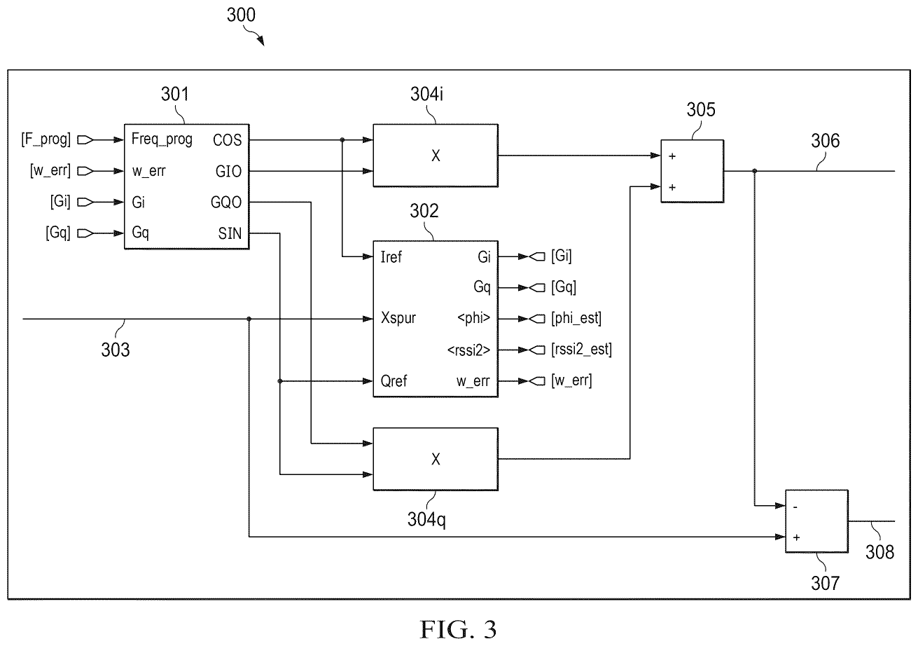

FIG. 2 is a flowchart of an example of method 200 for adaptive filtering in an ADC. In various embodiments, method 200 may be performed, at least in part, by spurious signal cancellation circuit 300 (of FIG. 3) implemented in connection with an ADC of device 100 (e.g., in wireless radio system 109).

Particularly, method 200 begins at 201. At 202, method 200 includes identifying the frequency of a spurious signal received or produced by the ADC. This frequency may be known a priori, or it may be estimated. The identification process may involve analyzing the ADC output to detect the presence of spurious tones and determining their respective frequencies. This can be achieved using various signal processing techniques, such as Fourier Transform or other spectral analysis methods.

At 203, method 200 may calculate coefficients (Gi, Gq) configured to track a phase and an amplitude of the spurious signal. These coefficients may be used to generate a compensation signal that can effectively cancel the spurious signal from the ADC's output. The calculation of Gi and Gq involves assessing the in-phase (I) and quadrature (Q) components of the spurious signal and determining the appropriate values that reduce or eliminate the spurious signal.

At 204, method 200 may provide a compensation signal based, at least in part, upon the calculated coefficients. Such a compensation signal may be configured to track the frequency, phase, and amplitude of the spurious signal. The compensation signal is generated by combining the in-phase and quadrature components, each scaled by the respective coefficients Gi and Gq. This signal is designed to have the same frequency, phase, and amplitude as the spurious signal but with an opposite polarity, thereby canceling it out when applied to the ADC output.

At 205, method 200 applies the compensation signal to an output of the ADC to cancel the spurious signal. This involves subtracting the compensation signal from the ADC output, effectively removing the spurious signal. Method 200 ends at 206, where the system may continue to monitor the ADC output for any new spurious signals and repeat the process as necessary.

FIG. 3 is a diagram of an example of spurious signal cancellation circuit 300. As used herein, the term “unit” refers to an electronic circuit, such as logic circuit, controller, or the like. In this implementation, circuit 300 includes control unit 301, processing unit 302, and logic cells 304i, 304q, 305, and 307 coupled as shown. In operation, ADC output 303 may contain a spurious signal, but compensated ADC output 308 does not.

To achieve this, control unit 301 is configured to receive, as inputs, a frequency of a spurious signal (freq_prog), a frequency error (w-err), Gi, and Gq. Control unit 301 is also configured to produce several outputs, including: Gio, Gqo, cos (I_{ref}), and sin (Q_{ref}).

Cell 304i produces [symbol] (A, φ)×I_{ref}, and cell 304q produces [symbol] (A, φ)×Q_{ref}. Meanwhile, cell 305 adds these terms to produce compensation signal 306 (i.e., [symbol] (A, φ)×I_{ref}+ [symbol] (A, φ)×Q_{ref}). Cell 307 subtracts compensation signal 306 from ADC output 303 to produce compensated ADC output 308.

Processing unit 302 is configured to receive, as inputs, ADC output 303 (Xspur) as well as control unit 301's cos and sin outputs. Moreover, processing unit 302 is configured to use these inputs to calculate Gi and Gq, as well as the phase (phi), RSSI (rssi2), and frequency error (w_err), which may then be provided to control unit 301.

In various embodiments, control unit 301 may operate following a Finite State Machine (FSM), such as the one shown in Table I:

TABLE I

| State | Description |
|---|---|
| 0 | Delay computations before buffers are fully loaded with samples |
| 1 | Estimation of frequency error between the programmed |
| | frequency and the spurious tone's effective or |
| | actual frequency |
| 2 | Estimation of the phase and amplitude of the spurious tone |
| 3 | Active state, freeze and apply [symbol] and [symbol] |

In some cases, control circuit 301 may also operate in a warm-up mode to assess and store coefficients cancelling spurious tones according to different settings to be used in active mode. As an example, the k-th setting parameter setting parameter “Pk” may select the operating channel frequency of a radio receiver. Spurious tones to be suppressed may be channel frequency selection dependent. Such a warm-up mode may allow, in this particular use case, to cancel unwanted tones linked to the system frequency plan according to the channel frequency to be selected. The learning state for a given Pk setting converges to the values Gi (Pk,t) and Gq (Pk,t) for each t tone which minimizes its power, and those value may then be stored in a Look-Up Table (LUT), or the like.

Additionally, or alternatively, control circuit 301 may implement a “time-multiplexed” learning mode and a “continuous time” learning mode. In the time-multiplexed learning mode, a learning update may be calculated for each Pk setting before useful signal samples are received, whereas in the continuous time learning mode, the learning update may be performed during active filtering. In some cases, selection between these two modes may be made depending, for example, upon one or more of: the amplitude of the spurious tone, a signal-to-tone ratio target, whether the modulated signal can be filtered in-band, or whether the spurious tone is sufficiently stable in phase and amplitude.

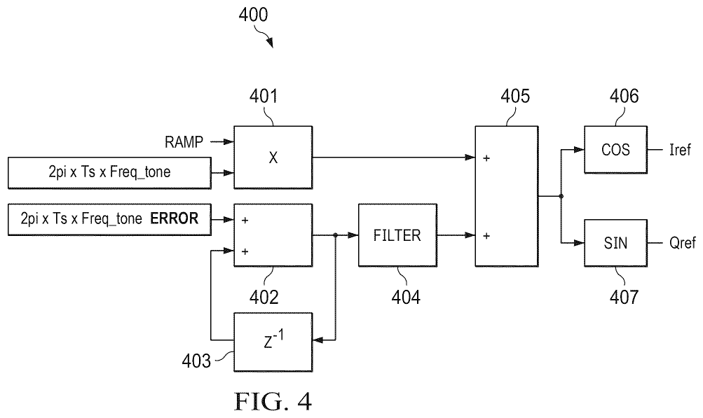

FIG. 4 is a diagram of an example of quadrature signal generation circuit 400 with optional frequency error compensation. In various embodiments, quadrature signal generation circuit 400 may be implemented within control unit 301 of spurious signal cancellation circuit 300.

As shown in circuit 400, unit 401 receives a ramp and input signal (2 pi×sampling period×spurious tone frequency) and outputs a reference signal with those characteristics, which is then provided to unit 405. Meanwhile, units 402 and 403 perform the frequency to phase error conversion—i.e., the time domain integration of the frequency error estimate (2 pi×sampling period×frequency error) received from processing circuit 500, and filter 404 mitigates noise before the estimate is provided to unit 405.

Unit 405 adds the outputs of units 401 and 404 to remove the frequency error from the reference signal. Moreover, units 406 and 407 may include one or more Look-Up Tables (LUTs) or the like configured to convert the output of unit 405 into quadrature reference signals I_{ref} and Q_{ref}.

Referring to back to FIG. 3, in various embodiments, processor 302 may assess the L2 norm (also known as the “Euclidian norm”) of the error vector on a selectable finite number of consecutive samples which can approximate the Mean Square Error. Furthermore, Gi and Gq may be computed through derivative calculation to minimize the L2 norm of the error vector computed over N consecutive samples of a programmable N number:

$${L}_{N}^{2} ( err ) = {\sum }_{i = 1}^{N} {( err ( i ) )}^{2} = {\sum }_{i = 1}^{N} ( ADC ( i ) - {G}_{I} \times {I}_{ref} ( i ) - {G}_{Q} \times )$$

$$\frac{\partial {L}_{N}^{2} ( err )}{\partial {G}_{Q}} = 0$$

$$or$$

$${\sum }_{i = 1}^{N} ( ADC ( i ) - {G}_{I} \times {I}_{ref} ( i ) - {G}_{Q} \times {Q}_{ref} ( i ) ) \times {I}_{ref} ( i ) = 0$$

$$\frac{\partial {L}_{N}^{2} ( err )}{\partial {G}_{I}} = 0$$

$$or$$

$${\sum }_{i = 1}^{N} ( ADC ( i ) - {G}_{I} \times {I}_{ref} - {G}_{Q} \times {Q}_{ref} ( i ) ) \times {Q}_{ref} ( i ) = 0$$

Adopting a notation where “ADCₛₚᵤᵣ” represents a vector of dimension N from N consecutive ADC output samples, I_{ref} is a vector of dimension N from N consecutive digitally synthesized cosine samples, and Q_{ref} is a vector of dimension N from N consecutive digitally synthesized sine samples:

$${\sum }_{i = 1}^{N} ( ADC ( i ) - {G}_{I} \times {I}_{ref} - {G}_{Q} \times {Q}_{ref} ( i ) ) \times {Q}_{ref} ( i ) = 0$$

becomes:

$$〈 {I}_{ref} \vert {ADC}_{spur} 〉 - {G}_{I} \times 〈 {I}_{ref} \vert {I}_{ref} 〉 - {G}_{Q} \times 〈 {I}_{ref} \vert {Q}_{ref} 〉 = 0 \qquad ( Eq . 1 )$$

$$And$$

$${\sum }_{i = 1}^{N} ( ADC ( i ) - {G}_{I} \times {I}_{ref} - {G}_{Q} \times {Q}_{ref} ( i ) ) \times {Q}_{ref} ( i ) = 0$$

becomes:

$$〈 {Q}_{ref} \vert {ADC}_{spur} 〉 - {G}_{I} \times 〈 {Q}_{ref} \vert {I}_{ref} 〉 - {G}_{Q} \times 〈 {Q}_{ref} \vert {Q}_{ref} 〉 = 0 \qquad ( Eq . 2 )$$

Solving Eq. 1 and 2 yields:

$${G}_{I} = \frac{〈 {Q}_{ref} \vert {ADC}_{spur} 〉 〈 {I}_{ref} \vert {Q}_{ref} 〉 - 〈 {I}_{ref} \vert {ADC}_{spur} 〉 〈 {Q}_{ref} \vert {Q}_{ref} 〉}{{( 〈 {I}_{ref} \vert {Q}_{ref} 〉 )}^{2} - 〈 {I}_{ref} \vert {I}_{ref} 〉 〈 {Q}_{ref} \vert {Q}_{ref} 〉} \qquad ( Eq . 3 )$$

$$And$$

$${G}_{Q} = \frac{〈 {I}_{ref} \vert {ADC}_{spur} 〉 〈 {I}_{ref} \vert {Q}_{ref} 〉 - 〈 {Q}_{ref} \vert {ADC}_{spur} 〉 〈 {I}_{ref} \vert {I}_{ref} 〉}{{( 〈 {I}_{ref} \vert {Q}_{ref} 〉 )}^{2} - 〈 {I}_{ref} \vert {I}_{ref} 〉 〈 {Q}_{ref} \vert {Q}_{ref} 〉} \qquad ( Eq . 4 )$$

where (A|B) is the scalar product of vectors A and B.

As such, Gi and Gq may be computed from Eq. 1 and 2 above to reduce or minimize the error between the received samples of the ADC, and the cosine and sine phases may be digitally generated to compensate for the spurious tone.

This scheme leverages vector-based processing to enhance efficiency. It offers a reduced convergence time, as no learning rate is defined. It also allows for increased accuracy of the frequency error, Gi, and Gq coefficients through the adjustment of the vector length parameter or the implementation of optional filters. Such optional filters include adaptable FIR or IIR filters and buffers length adjustments, further improving the circuit's performance.

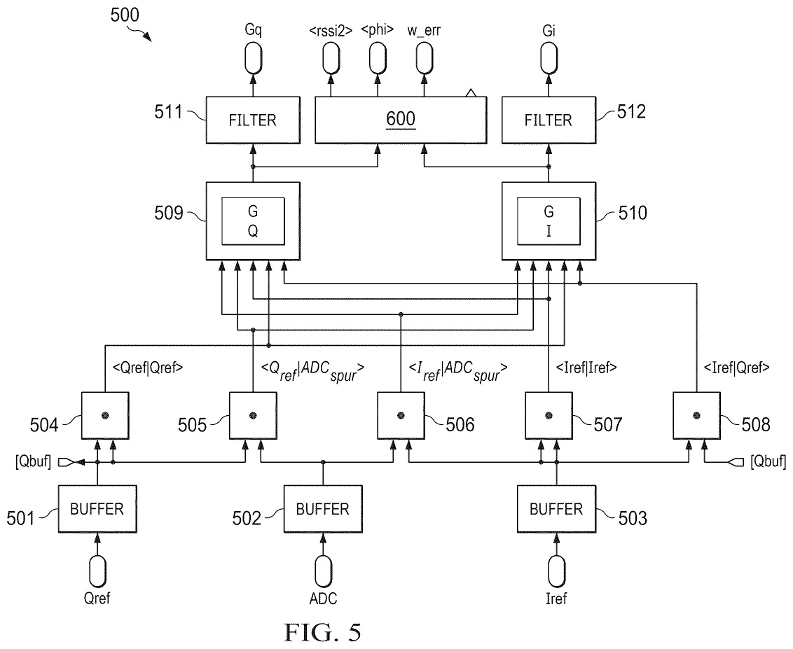

FIG. 5 is a diagram of an example of processing circuit 500 configured to estimate Gi and Gq. In various embodiments, processing circuit 500 may be implemented in processing unit 302 of spurious signal cancellation circuit 300.

As shown, buffers 501-503 are configured to store values for Q_{ref}, the ADC's output, and I_{ref}, respectively. Units 504-508 are coupled to the outputs of buffers 501-503 as shown and are configured to calculate different scalar products usable by Gq and Gi units 509 and 510 to produce estimate values for Gq and Gi using (Eq.3) and (Eq.4), respectively.

Particularly, unit 504 produces term:

$$〈 {Q}_{ref} \vert {Q}_{ref} 〉$$

Unit 505 produces term:

$$〈 {Q}_{ref} \vert {ADC}_{spur} 〉$$

Unit 506 produces term:

$$〈 {I}_{ref} \vert {ADC}_{spur} 〉$$

Unit 507 produces term:

$$〈 {I}_{ref} \vert {I}_{ref} 〉$$

And unit 508 produces term:

$$〈 {I}_{ref} \vert {Q}_{ref} 〉$$

Depending upon the size of buffers 501-503, Gq and Gi values may be filtered by filters 511 and 512, respectively, to remove noise. In addition, RSSI and frequency error estimation circuit 600 may be configured to receive estimate values for Gq and Gi from Gq and Gi units 509 and 510, respectively, and to produce values for RSSI, phase, and frequency errors.

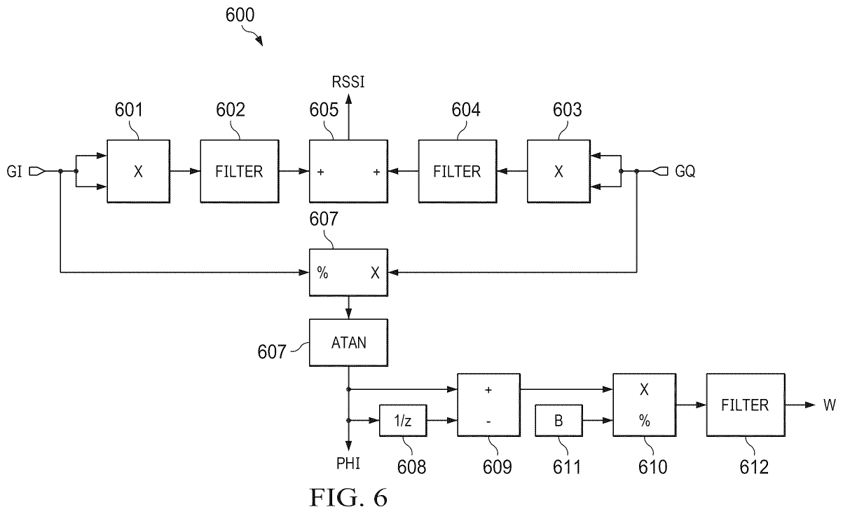

FIG. 6 is a diagram of an example of an RSSI and frequency error estimation circuit 600. In various embodiments, RSSI and frequency error estimation circuit 600 may be part of processing circuit 500, implemented in processing unit 302 of spurious signal cancellation circuit 300.

As shown, the estimated values for Gi and Gq are processed by units 601 and 604, respectively, to calculate their squares. After filtering by units 602 and 604 to remove noise, these values are added by unit 605 to produce an RSSI metric. In some cases, the RSSI metric may be used by control unit 301 to determine whether the spurious tone is significant enough to trigger adaptive filtering.

Estimated values for Gi and Gq are also provided to unit 606, which calculates the ratio Gq/Gi and sends it to atan unit 607. Atan unit 607 is configured to calculate the phase q (PHI) as atan (Gq/Gi). Unit 609 calculates a derivative of the phase using delay unit 608, which is then scaled using unit 610 based on scaling factor 611 (B). The output of unit 610 is processed by filter 612 to remove noise, thus providing a frequency error estimation of the spurious tone (w).

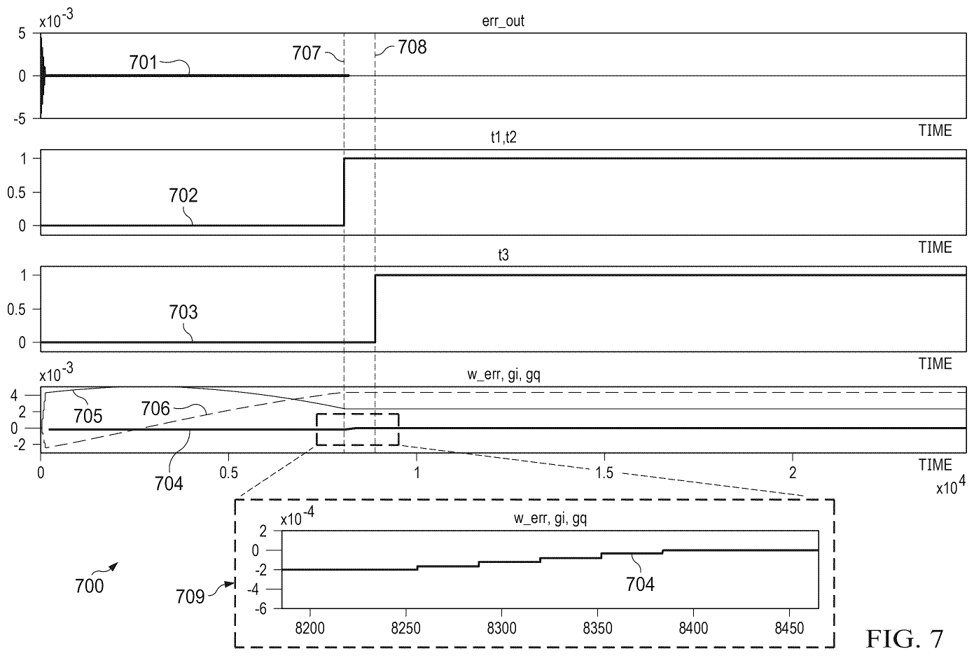

FIG. 7 is a graph 700 illustrating examples of adaptive filtering operations performed by the systems and methods described herein. In various embodiments, curves 701-706 show how spurious signal cancellation circuit 300 operates across different FSM states to produce a compensation signal that cancels the spurious tone.

Particularly, curve 701 shows an error between received and estimated spurious tone, curve 702 shows an enable signal that initiates the FSM's transition (Table 1) from state 1 (estimation of frequency error) to state 2 (estimation of phase and amplitude of the spurious tone) at time 707, and curve 703 shows another enable signal that initiates the transition from state 2 to state 3 (active filtering mode) at time 708.

Meanwhile, curve 704 shows the frequency error estimation (w_err), curve 705 shows values of Gi, curve 706 shows values of Gq as they are calculated and then frozen. View 709 zooms in to show how curve 704 changes in the time interval between 707 and 708 in more detail.

Concisely, graph 700 shows the values of the frequency error estimation, Gi, Gq change across the different FSM states, resulting in the elimination of the spurious tone in the FSM's active filtering state by introduction of a compensation signal, as shown by the flatness of curve 701 after time 708.

In sum, in various embodiments, systems and methods described herein may estimate and compensate for spurious signals in the output of an ADC. For example, a method for adaptive filtering or cancellation of unwanted signals by learning and applying coefficients to the in-phase (I) and quadrature (Q) components of a digital signal. In various implementations, these systems and methods may enable the cancellation of multiple unwanted signals simultaneously and may operate either before or during the reception of the signal.

For example, systems and methods described herein may provide spurious estimation and compensation by identifying the frequency, phase, and amplitude of spurious signals using Gi-Gq computation, which may reduce the learning phase compared to traditional adaptive techniques that use learning rate coefficients. These systems and methods may first estimate and compensate for frequency programming errors of the spurious signals, followed by gain and phase estimation.

In some cases, systems and methods described herein may estimate the frequency, phase, and gain of spurious signals before the reception of the useful signal, leading to better Signal-to-Noise Ratio (SNR) and faster convergence. Once the useful signal is received, the frequency, phase, and gain compensations can be frozen, ensuring no impact on the useful signal reception and reducing power consumption.

These systems and methods also provide a mechanism to assess the signal strength of the spurious signals to decide whether to activate the cancellation, thereby saving power when the spur level is low.

Additionally, the ADC's output path and the spurious estimation and compensation processing may be oversampled to compensate for high-frequency spurs closely below the ADC's Nyquist frequency, such as those at F_{ADC}/4 up to F_{ADC}/2. A warm-up mode may assess and store coefficients for canceling unwanted signals according to different settings, which may then be used in active mode. This allows for the cancellation of unwanted signals linked to the system frequency plan based on the selected channel frequency.

Accordingly, these features may collectively provide robust and efficient systems and methods for improving the performance of ADCs in various applications, particularly in orthogonal frequency division multiplex (OFDM) systems, such as Wi-Fi, 4G, or 5G, where spurious or unwanted signals can significantly impact the overall performance of subcarriers.

Systems and methods described herein may filter tones in a continuous learning and filtering state or act as a tone canceller in a learning freeze-active cancellation state; operating independently on the ADC I and ADC Q for complex signal digitization and includes a detector based on two metrics, RSSI and phase deviation, to determine the presence of a tone and enable the cancellation state in active mode.

In some embodiments, these systems and methods may assess the amplitude and phase of multiple unwanted tones using two loops per tone that select weights applied to quadrature digital tones, such that any number of spurious tones may be handled. Additionally, initial modes like warm-up infer the presence of unwanted tones, with the RSSI derived from IQ weights compared to a programmable threshold for tone cancellation.

Systems and methods described herein may also estimate and save coefficients for unwanted tone amplitude and phase in a LUT during warm-up, which can be fetched and updated before entering the active state and track these parameters in learning update states for narrow band modulated tones.

In summary, systems and methods for adaptive filtering in an ADC are described. In an illustrative, non-limiting embodiment, an electronic device may include an ADC and a circuit coupled to the ADC, the circuit configured to: calculate coefficients configured to track a phase and amplitude of a spurious signal received by the ADC; provide a compensation signal based, at least in part, upon the coefficients, where the compensation signal has the phase and amplitude; and apply the compensation signal to an output of the ADC to cancel the spurious signal.

The circuit may be configured to apply the signal to the output of the ADC, at least in part, in response to a determination that an RSSI of the spurious signal is greater than a threshold value. The circuit may also be configured to analyze a standard deviation phase of the spurious signal to validate an assumption of a narrowband interference.

In some cases, the circuit may be configured to estimate and compensate for frequency errors of the spurious signal. The circuit may also be configured to operate in a learning mode to calculate the coefficients prior to reception of a useful signal by the ADC. Additionally, or alternatively, the circuit may be configured to track and update the coefficients in real-time. Additionally, or alternatively, the circuit may be configured to oversample an ADC output to compensate for the spurious signal.

In some implementations, the circuit may be configured to: calculate other coefficients configured to track another phase and amplitude of another spurious signal received by the ADC; provide another compensation signal based, at least in part, upon the other coefficients, where the other compensation signal has the other phase and amplitude; and apply the other compensation signal to the output of the ADC to cancel the other spurious signal concurrently with the application of the compensation signal.

In another illustrative, non-limiting embodiment, a circuit may include a control portion configured to produce components of a spurious signal received by an ADC; a calculation portion coupled to the control portion, where the calculation portion is configured to calculate coefficients usable by the control portion to modify the components; and a signal estimation portion coupled to the control portion, where the signal estimation portion is configured to receive the modified components, produce a compensation signal having a frequency, phase, and amplitude of the spurious signal, and subtract the compensation signal from an output of the ADC.

The control portion may include a finite state machine (FSM) and a frequency programmable quadrature signal generator coupled to the FSM. The FSM may include: an initialization state, a phase and amplitude estimation state following the frequency error estimation state, and an active state following the phase and amplitude estimation state. In some cases, a frequency error estimation state may be implemented between the initialization state and the phase and amplitude estimate state. The control portion further may also include a frequency error compensation block coupled to the FSM and to the frequency programmable quadrature signal generator.

The calculation portion may be configured to estimate a frequency error of the spurious signal and to provide the frequency error to the frequency error compensation block, where the frequency error compensation block is configured to modify a frequency of the compensation signal based on the frequency error. The calculation portion may be further configured to determine whether an RSSI of the spurious signal is greater than a threshold value.

In yet another illustrative, non-limiting embodiment, a method may include identifying a first frequency of a first spurious tone; calculating first coefficients representative of a first phase and amplitude of the first spurious tone; providing a first compensation signal based, at least in part, upon the first coefficients, where the first compensation signal has the first frequency, phase, and amplitude; and applying the first compensation signal to an output of an ADC.

The method may apply the first compensation signal to the output of the ADC, at least in part, in response to a determination that a strength of the first spurious signal is greater than a threshold value. The method may also include estimating and compensating for frequency errors of the first spurious signal.

The method may include tracking and updating the coefficients in real-time. The method may also include identifying a second frequency of a second spurious tone; calculating second coefficients representative of a second phase and amplitude of a second spurious tone; providing a second compensation signal based, at least in part, upon the second coefficients, where the second compensation signal has the second frequency, phase, and amplitude; and applying the second compensation signal to the output of the ADC.

In many implementations, systems and methods described herein may be incorporated into a wide range of electronic devices including, for example, computer systems or Information Technology (IT) products; consumer devices or appliances; scientific instrumentation; industrial robotics; medical or laboratory electronics; transportation vehicles such as automobiles, buses, trucks, trains, watercraft, aircraft, etc.; military equipment, etc.

For sake of brevity, conventional techniques have not been described in detail herein. Furthermore, the connecting lines shown in the various figures contained herein have been intended to illustrate relationships (e.g., logical) or physical couplings (e.g., electrical) between the various elements. It should be noted, however, that alternative relationships and connections may be used in other embodiments. Moreover, circuitry described herein may be implemented either in silicon or another semiconductor material or alternatively by software code representation thereof.

Although various systems and methods are described herein with reference to specific embodiments, modifications and changes may be made without departing from the scope of the present disclosure, as set forth in the claims below. Accordingly, the specification and figures are to be regarded in an illustrative rather than a restrictive sense, and all such modifications are intended to be included. Any benefits, advantages, or solutions to problems that are described herein regarding specific embodiments are not intended to be construed as a critical, required, or essential feature or element of any or all the claims.

Reference is made herein to “configuring” a device or a device “configured to” perform some operation(s). This may include selecting predefined logic blocks and logically associating them. It may also include programming computer software-based logic of a retrofit control device, wiring discrete hardware components, or a combination thereof. Such configured devices are physically designed to perform the specified operation(s).

Unless stated otherwise, terms such as “first” and “second” are used to arbitrarily distinguish between the elements such terms describe. Thus, these terms are not necessarily intended to indicate temporal or other prioritization of such elements. The terms “coupled” or “operably coupled” are defined as connected, although not necessarily directly, and not necessarily mechanically. The terms “a” and “an” are defined as one or more unless stated otherwise. The terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs. As a result, a system, device, or apparatus that “comprises,” “has,” “includes” or “contains” one or more elements possesses those one or more elements but is not limited to possessing only those one or more elements. Similarly, a method or process that “comprises,” “has,” “includes” or “contains” one or more operations possesses those one or more operations but is not limited to possessing only those one or more operations.

1. An electronic device, comprising:
an Analog-to-Digital Converter (ADC); and
a circuit coupled to the ADC, the circuit configured to:
calculate coefficients configured to track a phase and amplitude of a spurious signal received by the ADC;
provide a compensation signal based, at least in part, upon the coefficients, wherein the compensation signal has the phase, and amplitude; and
apply the compensation signal to an output of the ADC to cancel the spurious signal.

2. The electronic device of claim 1, wherein the circuit is configured to apply the signal to the output of the ADC, at least in part, in response to a determination that a Received Signal Strength Indicator (RSSI) of the spurious signal is greater than a threshold value.

3. The electronic device of claim 1, wherein the circuit is configured to analyze a standard deviation phase of the spurious signal to validate an assumption of a narrowband interference.

4. The electronic device of claim 1, wherein the circuit is configured to estimate and compensate for frequency errors of the spurious signal.

5. The electronic device of claim 1, wherein the circuit is configured to operate in a learning mode to calculate the coefficients prior to reception of a useful signal by the ADC.

6. The electronic device of claim 1, wherein the circuit is configured to track and update the coefficients in real-time.

7. The electronic device of claim 1, wherein the circuit is configured to oversample an ADC output to compensate for the spurious signal.

8. The electronic device of claim 1, wherein the circuit is configured to:
calculate other coefficients configured to track another phase and amplitude of another spurious signal received by the ADC;
provide another compensation signal based, at least in part, upon the other coefficients, wherein the other compensation signal has the other phase and amplitude; and
apply the other compensation signal to the output of the ADC to cancel the other spurious signal concurrently with the application of the compensation signal.

9. A circuit, comprising:
a control portion configured to produce components of a spurious signal received by an Analog-to-Digital Converter (ADC);
a calculation portion coupled to the control portion, wherein the calculation portion is configured to calculate coefficients usable by the control portion to modify the components; and
a signal estimation portion coupled to the control portion, wherein the signal estimation portion is configured to receive the modified components, produce a compensation signal having a frequency, phase, and amplitude of the spurious signal, and subtract the compensation signal from an output of the ADC.

10. The circuit of claim 9, wherein the control portion further comprises:
a finite state machine (FSM); and
a frequency programmable quadrature signal generator coupled to the FSM.

11. The circuit of claim 10, wherein the FSM comprises: an initialization state, and a phase and amplitude estimation state following the initialization state.

12. The circuit of claim 11, wherein the FSM further comprises an active state following the phase and amplitude estimation state.

13. The circuit of claim 10, wherein the control portion further comprises a frequency error compensation block coupled to the FSM and to the frequency programmable quadrature signal generator.

14. The circuit of claim 13, wherein the calculation portion is further configured to estimate a frequency error of the spurious signal and to provide the frequency error to the frequency error compensation block, wherein the frequency error compensation block is configured to modify a frequency of the compensation signal based on the frequency error.

15. The circuit of claim 14, wherein the calculation portion is further configured to determine whether a Received Signal Strength Indicator (RSSI) of the spurious signal is greater than a threshold value.

16. A method, comprising:
identifying a first frequency of a first spurious tone;
calculating first coefficients representative of a first phase and amplitude of the first spurious tone;
providing a first compensation signal based, at least in part, upon the first coefficients, wherein the first compensation signal has the first frequency, phase, and amplitude; and
applying the first compensation signal to an output of an Analog-to-Digital Converter (ADC).

17. The method of claim 16, further comprising applying the first compensation signal to the output of the ADC, at least in part, in response to a determination that a strength of the first spurious signal is greater than a threshold value.

18. The method of claim 16, further comprising estimating and compensating for frequency errors of the first spurious signal.

19. The method of claim 16, further comprising tracking and updating the coefficients in real-time.

20. The method of claim 16, further comprising:
identifying a second frequency of a second spurious tone;
calculating second coefficients representative of a second phase and amplitude of a second spurious tone;
providing a second compensation signal based, at least in part, upon the second coefficients, wherein the second compensation signal has the second frequency, phase, and amplitude; and
applying the second compensation signal to the output of the ADC.
